(19) United States
(12) Patent Application Publication
(10) Pub. No.: US 2003/0001286 A1
(43) Pub. Date: Jan. 2, 2003

(54) Semiconductor package and flip chip bonding method therein

(76) Inventors: Ryoichi Kajiwara, Hitachi (JP); Masahiro Koizumi, Hitachi (JP); Toshiaki Morita, Hitachi (JP); Kazuya Takahashi, Hitachinaka (JP); Asao Nishimura, Kokubunji (JP); Kunihiro Tsubosaki, Hino (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 10/233,558

(22) Filed: Sep. 4, 2002

Related U.S. Application Data
(63) Continuation of application No. 09/463,603, filed on Jan. 28, 2000.

(51) Int. Cl. H01L 23/48; H05K 3/32

(52) U.S. Cl. 257/778; 257/737; 438/108; 257/786; 438/612; 438/613; 29/840; 29/740

(57) ABSTRACT

A semiconductor chip and an organic substrate are bonded together in an atmosphere having a reduced moisture content through Au bumps which have been subjected to a cleaning treatment therebetween. Using this bonding technique, a semiconductor chip and an organic substrate can be bonded together in a sufficiently high strength with use of Au bumps having a diameter of not larger than 300 μm, a height of not smaller than 50 μm, and a height/diameter ratio of not lower than 1/5, thus indicating a reduced strain.

### TECHNICAL FIELD

The present invention relates to a semiconductor package having a structure wherein a semiconductor chip, such as an LSI chip, is mounted on a carrier substrate formed of an organic material.

### BACKGROUND OF THE INVENTION

Heretofore, a method of connecting a semiconductor chip to a substrate by a flip chip bonding technique, a method using solder bumps has been known as a C4 technique. According to this method, solder bumps are formed on chip-side Al electrode pads through a barrier metal, while Au plating superior in solder wettability is applied to substrate-side connecting terminals, and a solder is caused to reflow in a fluxless non-oxidizing atmosphere to effect bonding of the chip to the substrate. In the case where the substrate being used is a ceramic substrate, the substrate is used as a hermetic sealing, while in the case of an organic substrate, a resin-silicon compound which has been adjusted to the thermal expansion coefficient is filled between a chip and resin to enhance the reliability of a soldered portion.

On the other hand, Au bump/Au pad flip chip bonding methods without using solder have been known, including a thermocompression bonding method and a thermosonic bonding method. Conventional conditions for thermocompression bonding involve a heating temperature of 350° C., a load of 150 to 250 g/bump, and the number of bumps on a chip of less than 50. Likewise, conventional conditions for thermosonic bonding involve a heating temperature of 200° C., a load of 300 g, and six bumps or so on a chip. In both cases, a carrier substrate made of a ceramic material is used. In thermocompression bonding, the load is lowered by raising the heating temperature, but a load of 150 g/bump is still required. In thermosonic bonding, the heating temperature is reduced to 200° C., but a load as high as 300 g/bump is still required. These conditions were found as a result of various studies made for attaining a positive Au/Au bond in the air. Lower temperature and lower load conditions are not applicable to the actual product assembly because the bonding would become unstable. In both compression bonding methods mentioned as above, the compression-bonded shape of an Au bump affords a bonded portion of a largely crushed shape having a thickness of 15 to 25 μm and a diameter of 150 μm or more as typical sizes.

Another conventional Au bump/Au pad connecting method is known wherein both are subjected to compression bonding under heating with use of an electrically conductive resin as an adhesive which is interposed therebetween. According to this method, resin is filled and solidified between a chip and a substrate, thereby attaining a predetermined long-term reliability.

With the development of an ultra-fine wiring technique, the recent LSI chips are becoming higher and higher in the degree of integration, and the pad pitch is becoming narrower rapidly as the number of pins on a chip increases or as with the chip reduced in size. In the case of mounting such a chip to a package, the conventional peripheral pad bonding technique gives rise to two problems. That is, in TAB and wire bonding, a bondable pad pitch encounters a limit at a level of 40 μm. Since wiring from a chip terminal to an external terminal of the package cannot be provided along the shortest route, the wiring inductance increases, causing a delay in signal transmission, and the processing speed decreases.

According to a method proposed to solve the above-mentioned problems, electrode terminals of a chip are arranged areawise on the whole surface of the chip. The solder bump bonding method (C4) already employed in the field of conventional large-sized computers can solve the foregoing two problems, but when it is applied to a semiconductor package, there arises a problem concerning the soldering temperature. More particularly, in a large-sized computer, a high-melting solder (95Pb-5Sn solder melting at 300° C.) is used for soldering a chip because of the necessity for subsequent hierarchical soldering. Generally, a suitable soldering temperature is about 50° C. higher than the melting point of the solder being used, so that, when the substrate material is not a ceramic, but is an organic material, it is impossible to use such a high-melting solder because the substrate will undergo a heat deterioration. If a solder is used which has a solid phase temperature in the range of 200° C. to 240° C., there will arise a problem in that, in a eutectic soldering process for mounting a semiconductor package onto a wiring board, a soldered portion inside of the package partially melts again and causes a failure due to breaking of the wire. Thus, in the internal connection of a semiconductor package, a connection having a heat resistance of not lower than 250° C. must be realized while bonding at a low temperature of not higher than 250° C.

A known bonding method suitable for this requirement is a flip chip bonding method using Au bumps. According to this bonding method, Au, which has a high melting point and is superior in bondability, is formed into a bump shape and compression bonding is performed in a solid phase by heating or by using an ultrasonic wave, thus permitting a heat-resistant bonded portion at a low bonding temperature. In the conventional Au bump bonding method, however, such a large bonding load as 300 g per bump is required, and in the actual case of a chip having 100 to 2,000 bumps, the load applied to the chip reaches 30 to 600 kg. Consequently, chipping or cracking of the chip caused by a local abutment of a pressing tool against the chip poses a serious problem. According to experiment, a maximum load applicable to the chip is presumed to be in the range of about 20 to 40 kg, so that the actual application of the conventional bonding method is difficult unless a highly reliable bonding can be performed at a bonding load of 20 g to 80 g per bump. If the bonding temperature can be raised in the conventional thermocompression bonding method, it is possible to effect a reliable bonding in a low load condition. However, since the substrate is formed of an organic material, the heating temperature cannot be raised above 250° C. even for a polyimide having heat resistance and above 200° C. for use of an epoxy resin from the standpoint of avoiding heat damage. In a thermosonic bonding method capable of effecting a reliable bonding at a low heating temperature and a relatively low load, a high ultrasonic energy is required for obtaining a reliable bonded portion, thus giving rise to the problem that the chip is damaged by ultrasonic oscillation. Further, both thermocompression bonding and ultrasonic compression bonding afford a considerably crushed bump shape after bonding, so that, as the pad pitch becomes as narrow as 200 μm or so due to chip shrink, there arises a problem of a short-circuit with an adjacent pad due to bump deformation. At the same time, the spacing between adjacent bumps becomes 50 μm or so at a height of about 20 μm, so that when resin is filled, voids are apt to occur and the filling of an under-fill resin becomes difficult, thus causing the problem of deterioration in reliability as a package.

On the other hand, the method using Au bumps and an electrically conductive resin performs a compression bonding at a low heating temperature and a low bonding load as a bonding condition so that it is possible to bond, diminishing the deformation of the bumps; and, besides, since the compression bonding in this method is performed after pre-filling resin between a chip and a substrate in a connecting process, it is possible to assemble a good package free of voids. However, in the case of an electrically conductive resin, the state of contact of its conductive particles is deteriorated due to a cubical expansion caused by moisture absorption and there arises a problem in reliability that the resistance increases with the lapse of time.

Recently, as a measure for reducing the package cost, there has been proposed a chip scale package of the type in which assembly to a package is performed at the stage of wafer. For mounting a package to a wiring board, there usually is adopted a structure wherein the package is bonded to the wiring board through solder ball bumps. In this case, ensuring reliability without reinforcing the soldered portion with an under-fill resin is important in terms of reducing the package mounting cost and ensuring repairability. To this end, it is necessary to adopt a structure in which a heat strain is relieved in a portion other than the soldered portion so as to prevent the heat strain from being concentrated in the soldered portion, in which heat strain is generated due to a difference between the thermal expansion coefficient of an Si chip and that of a wiring board. Thus, in the case of a BGA package, a structure usually is used which uses an organic carrier substrate. However, a wafer-state bonding to the carrier substrate causes the generation of a large strain proportional to the wafer size in a bonded area around the wafer due to a difference in thermal expansion between the carrier substrate and the Si wafer. The magnitude of the induced strain is proportional to the bonding temperature and inversely proportional to the bump height. In the conventional bonding performed with the use of solder, the soldering temperature during the package assembly becomes inevitably high from the standpoint of soldering resistance in the mounting of the package to a wiring board, with consequent increase in magnitude of the strain and a low solder strength. For this reason, there arises a in problem that a large strain is induced in a soldered area around wafer, causing damage, when the work concerned is cooled to room temperature after bonding. On the other hand, in the bonding structure using Au bumps, a bondable heating temperature in the prior art is 70° C. or higher from the standpoint of improving bondability by desorption and interfacial diffusion of adsorbed molecules. At a low temperature of not higher than 200° C., a large plastic deformation of Au bumps is essential to bonding. Thus, it has so far been difficult to increase the shape after compression bonding to 1/5 or more in terms of aspect ratio (height/diameter ratio). Particularly, at a bonding temperature of not higher than 130° C., the aspect ratio has been 1/10 or less and thus extremely low. Assuming that the bonding temperature is 70° C., a heat strain of the bonded product can be roughly calculated as follows using a structure model shown in FIG. 19. In the case where the wafer size is 8 inches, the occurrence of a deviation of 0.060 mm can be confirmed in a bump bonded-area around the wafer on the basis of a difference between the thermal expansion coefficient of Si, α=3×10⁻⁶/K, and that of a 108-6 carrier tape substrate, α=15×10⁻⁶/K. This deviation is absorbed by deformation of the bumps, deformation of the substrate and deformation of the Si wafer. In this case, a share of the strain taken up by the Si wafer and the carrier substrate are calculated roughly from a stress balance. Young's moduli of these components are Si:190 GPa, Au bump: 88 GPa, and polyimide substrate:9 GPa. Since a sectional ratio is determined by the thickness of each component and a space volume ratio of the Au bumps, if the bump height is assumed to be H and a deviation in a vertical shearing direction of Au bumps is Δ, a main strain (ε) in a bump tensile direction is represented as ε=((H²+A²)^{1/2}−H)/H in a two-dimensional model and the relation between the bump height and the main strain is represented by such a curve as shown in FIG. 20. On the other hand, the elongation of Au bumps depends on the material and it is in the range of 3% to 6% in the case of forming Au bumps by plating or ball bonding. In such a condition, when the main strain exceeds this value, there will occur breakage of the Au bumps. More particularly, when the bonding temperature is 70° C., even a bump having a sufficient bonding strength is required to be 50 μm or more in bump height, and in the case of a bonding temperature of 200° C., it is necessary that the bump height be 80 μm or more. If the bonding strength between a chip or a substrate and Au bumps is low, it becomes necessary to ensure a much larger bump height. Therefore, when the Au bump height is set at a minimum height not causing breakage of Au bumps due to heat shrink after bonding, i.e., 50 μm at a bonding temperature of 70° C., the compression bond diameter becomes 500 μm or larger; likewise, under the conditions of a bonding temperature of 200° C. and a bump height of 80 μm, the compression bond diameter becomes 400 μm or larger. Thus, taking variations in compression bond diameter and in shape into account, it has been difficult to narrow the bump pitch to 500 μm or less.

### SUMMARY OF THE INVENTION

It is an object of the present invention to provide a semiconductor package containing a semiconductor chip, such as an ultra-multi-pin or high-speed LSI chip or the like, which is capable of making the most of the chip performance and having an internal connection with high heat resistance and high reliability. It is another object of the present invention to provide a chip/substrate flip chip bonding method and apparatus which are capable of achieving a low-temperature process, mass-productivity and a high yield, which are required for realizing the semiconductor package stated above.

It is a further object of the present invention to provide a mounting structure-in the case where a wafer-lebel mounting process is carried out, which does not cause a problem of damage to a bonded portion due to heat strain in a cooling process after wafer-organic carrier substrate bonding and which can diminish the bump pitch, as well as a low cost wafer-stage package mounting method.

In the semiconductor package structure according to the present invention, an organic carrier substrate and a semiconductor chip are spaced apart 50 9 m or more, both are bonded in this state firmly metallically through areawise arranged Au bumps as an intermediate material, and the gap therebetween is filled with resin. In the bonding method according to the present invention, a material constitution of Au/Au is adopted for a flip chip bonded surface, the degree of cleanness of the said bonded surface is specified, and compression bonding is performed under application of heat in a dry atmosphere having a moisture content of 100 Pa or less in terms of a partial pressure of steam or under scrubbing or application of a weak ultrasonic oscillation. This bonding method can afford the foregoing semiconductor package according to the present invention.

Results of studies made by the present inventors, which underlie the present invention, will be referred to below.

Generally, Au has a strength of 14 to 25 kg/mm² and does not undergo a work hardening, so its fatigue life is longer by one digit or more than the solder, so if flip chip bonding using Au bumps can be performed, the package will be improved in its temperature cycle reliability. However, it is necessary to considerably crush the Au bumps, or else it would be impossible to obtain a reliable bonded portion having a sufficient bonding strength. Consequently, there arise a problem of damage to the chip caused by a bonding load or ultrasonic oscillation and a problem that the filling of resin cannot be done sufficiently because the chip-to-substrate gap becomes too narrow. Thus, the application of Au bumps is difficult in a semiconductor package using an organic substrate. On the other hand, in the bonding of noble metals such as Au and Ag, if the metal surfaces are made clean in an ultra-high vacuum, it is possible to effect compression bonding while minimizing the deformation of bumps under the conditions of a normal temperature and a low load. However, for application to a mass production line of semiconductor packages, there remains a problem concerning a handling mechanism which effects registration of the chip and the substrate after cleaning in a vacuum and also in the process tact concerned. Thus, the application of the bonding method in question to actual products is difficult from the point of view of both mass productivity and production cost. In more particular terms, this is because it is difficult to chuck the chip and the substrate in a vacuum, because the alignment mechanism is expensive if it is constituted using an evacuatable material, and further because a high-speed operation in a vacuum is apt to cause wear or seizure of the moving components, leading to a shorter service life of the apparatus. If one could provide a bonding method which can be carried out in atmospheric pressure and which is capable of affording bondability equal to that in a vacuum, it will become possible to solve the abovementioned problem, facilitate handling of the chip and the substrate, and operate various mechanical portions at high speed.

On the basis of such a thought, we have made various studies about a clean surface state and a bonded state. FIG. 12 shows the results of bonding performed by ultrasonic-bonding Au balls to an Au deposited film at a heating temperature of 100° C. in air and in a nitrogen atmosphere. The bonding load was 50 g. In the same figure, an ultrasonic output is plotted along the abscissa and a ratio of 16 g or more in bonding strength is plotted along the ordinate. In both atmospheres, the results of bonding shown therein are plotted as in the case where the surface of the Au film is not treated and the case where it has been cleaned by the ion radiation. An ultrasonic output which affords 100% successful bonding is 0 mW in a cleaned surface condition and in a nitrogen atmosphere; that is, bonding could be done by the load alone. In nitrogen, 100% bonding is reached at 1.4 mW even without cleaning. In contrast therewith, in the air, it is at 15 mW that 100% successful bonding is obtained even after surface cleaning, and a load of 151 mW is required if cleaning is not performed. In other words, bonding in nitrogen for an uncleaned surface is superior in bondability to bonding in air for a cleaned surface. FIG. 13 shows the results of having checked the degree of surface contamination by Auger analysis. In the case of an untreated sample, organic matter contamination or S contamination is pronounced and Au concentration on the surface is as low as 33 atom %. In contrast therewith, a sample which has been subjected to a surface cleaning treatment is lower in contamination level than the untreated sample, even when exposed to nitrogen or the atmosphere, and the Au concentration on the surface is at a high level of 55 to 61 atom %. Thus, in Au/Au bonding, it is not only the surface contamination level which determines bondability thereof, but the influence of atmospheric gas is significant.

Next, therefore, for studying what atmospheric gas affects bondability, gases contained in the atmosphere were analyzed and the influence on bondability of gases contained therein other than nitrogen was studied. FIG. 14 shows a gas composition of the atmosphere (air). Oxygen and moisture are presumed to be gases which affect bondability. Therefore, we have prepared an atmosphere containing such gases, performed bonding therein and compared bondability. FIG. 15 shows the results of bonding performed in an Ar gas atmosphere containing oxygen or moisture, bonding performed in air and bonding performed in nitrogen atmospheres. In the same figure, hatched areas represent ultrasonic wave output areas affording 100% successful bonding. It is seen that oxygen exerts no influence on bondability and that moisture exerts a bad influence thereon. FIG. 16 shows a relation between the content of moisture in an atmospheric gas used and a minimum ultrasonic wave output which affords 100% successful bonding. A correlation is clearly recognized between these two and an abrupt deterioration of bondability is recognized from a moisture content of 0.03 to 0.1 vol %. That is, if the moisture content in the atmosphere used is in the range of 0.03 to 0.1 vol %, Au balls and Au pads can be bonded together to a bonding strength of 16 g or higher by performing a surface cleaning treatment and under low temperature and low load conditions of 100° C. and 50 g, respectively. From these results, it is apparent that in Au bonding the control of moisture contained in the bonding atmosphere used is very important. If the moisture is properly controlled, a sufficient bonding strength is obtained by cleaning the Au bonding surface so as to become 20 atom % or more in terms of the Au concentration thereof.

If this result is applied, then by combining the surface cleaning treatment with a bonding method in a moisture-controlled atmosphere, a chip formed with Au bumps can be bonded to Au pads or Au bumps on an organic substrate of high strength while preventing deformation of the bumps under the conditions of a load not higher than 50 g per bump and a bonding temperature of 100° C. to 200° C. In other words, by the application of surface cleaning and an Au bump/Au pad bonding method in a controlled atmosphere, it becomes possible to package an ultra-multi-pin or high-speed LSI chip and make the most of the chip performance: besides, it is possible to realize a package structure having a bonded portion with a high long-term reliability. Additionally, such a semiconductor package can be assembled with high mass productivity and high yield.

Semiconductor packages were assembled in accordance with this method and then subjected to reliability tests, the results of which are shown in FIGS. 17 and 18. FIG. 17 shows the results of a temperature cycle test for packages having different Au bump heights, with chip size being in the range of 5 to 10 mm square. It is apparent that the bump height and the breaking life are correlated with each other, and it is when the bump height is about 50 μm or more that the life exceeds a practically required life of 1,000 times. FIG. 18 shows the results of having checked the relation between bump bonding strength and the rate of breakage occurrence in the case of repeated solder reflow. At a bump strength of 20 g, there is recognized the occurrence of breakage, although the probability thereof is small. Thus, from the standpoint of package reliability, it is desirable that the bump height be 50 μm or more and the bump strength 30 g or more.

The following description is now provided about bonding of a carrier substrate on a wafer level. By adopting the bonding method according to the present invention, it is possible to effect bonding at a small crushing ratio, as shown in FIG. 21, at a bonding temperature of 70° C. to 100° C. Strain between an Si wafer and a carrier substrate is about 60 μm in model conditions shown in FIG. 19 and there is a bump height-main strain relation as shown in FIG. 20. If the bonding temperature and bump height are set at 70° C. and 50 μm, respectively, a main strain becomes about 3% and a stress of 13 to 20 kg/mm² is induced. If the bonded interface strength of Au bumps is lower than this value, there will occur breakage at the interface, so it is necessary to obtain a sufficiently high bonding strength. In the prior art, a sufficient bonding strength is not obtained unless the bump crushing ratio is increased to 50% or more, so that a bump diameter of 420 μm is required for attaining a bump height of 50 μm, and thus it is difficult to realize a pitch of 500 μm or less. But, if a bonding method is adopted, which is carried out for cleaned surfaces in a dry atmosphere, bonding can be done at a crushing ratio of 22% and an aspect ratio of 0.52, so that it becomes possible to realize a bump height of 50 μm at a compression bond diameter of 100 μm. That is, it becomes possible to effect a 200 μm-pitch bonding. Conversely, by setting the bump diameter and bump height at 200 μm and 100 μm, respectively, it is possible to diminish strain to 0.3% and an intra-bump induced stress is 2.6 kg/mm², thus suppressing deformations to an elastic range of deformations, with no fear of damage to the bonded portion.

On the basis of the above studies, the present invention has been accomplished by providing a bonding method wherein consideration is given to the cleaning of the Au surface and to the amount of moisture in a bonding atmosphere, as will be described in detail later. The following novel semiconductor packages are obtained by the bonding method according to the present invention.

1) A semiconductor package wherein electrode terminals of a semiconductor chip and internal connection terminals of an organic substrate are bonded together through Au bumps having a diameter of 300 μm or less, a height of 50 μm or more and a height/diameter ratio of 1/5 or more.

2) A semiconductor package wherein a plurality of electrode terminals of a semiconductor chip and a plurality of internal connection terminals arranged on an organic substrate in a dimensionally identical manner with those electrode terminals are connected to each other through Au bumps, and a plurality of external connection terminals of the organic substrate are constituted by solder bumps having a liquid phase temperature of 190° C. or higher.

3) A semiconductor package wherein a semiconductor chip and a plurality of internal connection terminals on an organic substrate are flip chip-bonded through Au bumps with a pitch of 400 μm or less, an area of external connection terminals and that of internal connection terminals on the organic substrate are divided by slits, and the external and internal connection terminals are connected to each other through wires extending through the slits.

4) A semiconductor package wherein a semiconductor chip and a plurality of internal connection terminals arranged areawise on an organic substrate are bonded together in a facedown manner through Au bumps, and an area of internal connection terminals and that of external connection terminals overlap each other on a projection surface.

5) A semiconductor package wherein a plurality of semiconductor chips having electrode terminals and arranged at intervals of 1 mm or less and a plurality of internal connection terminals on an organic substrate are connected to each other through Au bumps, and external connection terminals of the organic substrate are constituted by solder bumps having a liquid phase temperature of 190° C. or higher.

In each of the above semiconductor packages, it is preferable that resin be filled between the semiconductor chip and the organic substrate.

### BRIEF DESCRIPTION OF THE DRAWINGS

FIG. 1 is a sectional view of a semiconductor package according to the present invention.

FIGS. 2A and 2B are diagrams showing Au bump shapes.

FIG. 3 is a sectional view of a semiconductor package according to the present invention.

FIG. 4 is a sectional view of a semiconductor package according to the present invention.

FIG. 5 is a plan view of an organic carrier substrate to be used in the semiconductor package of FIG. 4.

FIG. 6 is a sectional view of a multi-tip semiconductor package according to the present invention.

FIG. 7 is a process flow diagram of a bonding procedure adopted to a chip-carrier substrate bonding method according to the present invention.

FIG. 8 is a diagram of a system configuration for realizing the bonding method illustrated in FIG. 7;

FIG. 9 is a process flow diagram of a bonding procedure adopted to a chip-carrier substrate bonding method according to the present invention.

FIG. 10 is a diagram of a system for realizing the bonding method illustrated in FIG. 9.

FIG. 11 is a diagram of a system including the pretreatment chamber and the bonding chamber illustrated in FIG. 10.

FIG. 12 is a graph which shows test results indicating how a bonding atmosphere of nitrogen and that of air exert an influence on bonding results.

FIG. 13 is a graph which shows the results of Auger analysis which indicating to what degree bonding surfaces are contaminated.

FIG. 14 is a table which shows a gas composition of an air atmosphere.

FIG. 15 is a bar graph which shows experimental results which indicate how various bonding atmospheres exert an influence on bonding results.

FIG. 16 is a graph which shows experimental results indicating how the moisture content of a bonding atmosphere exerts an influence on bonding results.

FIG. 17 is a graph which shows the results of a temperature cycle test conducted for semiconductor packages according to the present invention.

FIG. 18 is a graph which shows the results of a solder reflow repeating test conducted for semiconductor packages according to the present invention.

FIG. 19 is a diagram of a semiconductor package model.

FIG. 20 is a graph which shows a height-strain relation of a bump.

FIG. 21 is a graph which shows a ratio of crushing-bonding strength relation.

### BEST MODE FOR CARRYING OUT THE INVENTION

Embodiments of the present invention will be described below in detail with reference to the accompanying drawings.

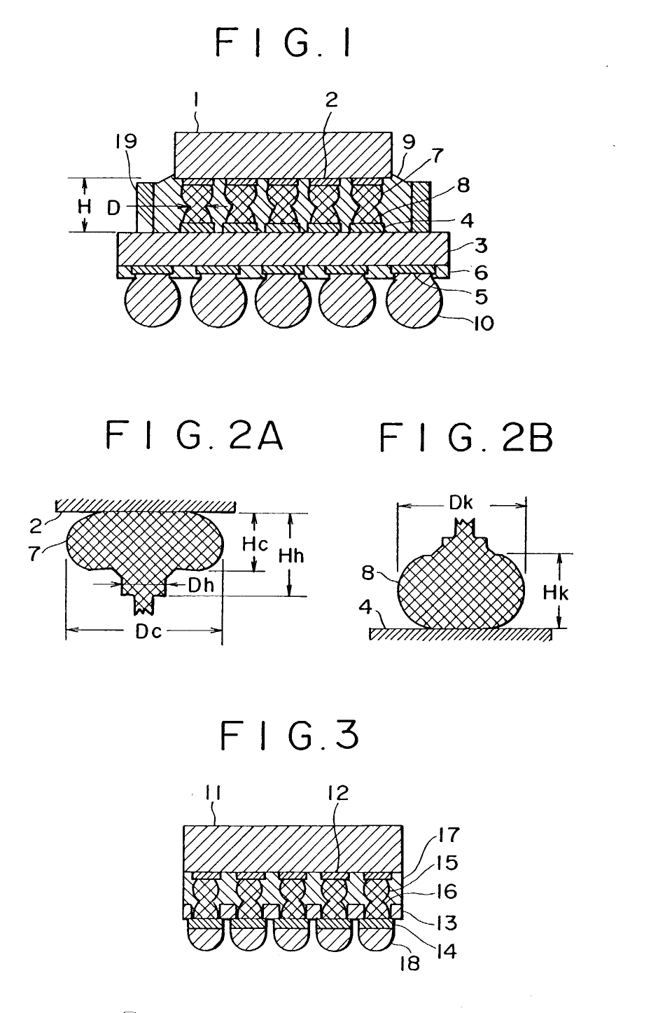

FIG. 1 shows a sectional view of a structure of a semiconductor package according to the present invention. In the same figure, Au bumps 7 are formed by ball bonding on Al or Au electrode pads 2 formed on a semiconductor chip 1 (hereinafter referred to as the “chip 1”). An organic carrier substrate comprises an organic insulating plate 3, internal connection terminals 4 formed on one surface of the organic insulating plate 3, external connection terminals 5 formed on a surface opposite to the surface side of the organic insulating plate 3, and a plated resist 6 which covers the surface of the insulating plate around the external connection terminals 5. The internal and external connection terminals 4 and 5 are formed by a method wherein etching is performed through Cu plating or Cu foil. Those terminals are electrically interconnected through through-holes, and wiring formed in the organic substrate 3 and their outermost surfaces are plated with Au after Ni or Pd plating as an undercoat. The assembly of the package is carried out in the following manner. Au bumps 8 are formed on the internal connection terminals 4 of the carrier substrate by ball bonding and are then aligned with the Au bumps 6 of the chip 1 so that both Au bumps come into contact with each other, the surrounding atmosphere is evacuated to 1 Pa or less, followed by heating to a temperature of 150° C. to 250° C. to effect compression bonding. The load applied is 30 to 80 g/bump and a displacement quantity control is carried out during the bonding work to prevent the bumps from being excessively crushed.

FIGS. 2A and 2B show initial shapes of Au bumps formed by ball bonding, in which a chip-side ball bump shape FIG. 2A is obtained by suitably selecting discharge and bonding conditions and a capillary tool shape so that the compression bond diameter Dc is 110±10 μm, the shoulder height Hc with which a tip end face of the capillary tool has been in contact is 25±5 μm, the diameter Dh of a central swollen portion of each bump is 50 μm, and the height Hh of that portion is 50±10 μm. A bonding strength of 80 g or more in terms of shear strength is obtained. On the other hand, a substrate-side ball bump shape FIG. 2B is obtained by making the deformation of the ball smaller than that on the chip side and adopting a shoulder height-Hk of 40±10 μm, which is higher than that of the chip side. In this ball bonding, the bonding terminal surface of the substrate is subjected to sputter cleaning just before bonding with a view to improving bondability. A bonding strength of 50 g or more is obtained in terms of shear strength. Both bumps are compression-bonded together while controlling the amount of the bumps to be crushed by a displacement quantity control so that the bumps are bonded metallically with each other at the respective central swollen portions. In a bump column resulting from the bonding, the bonded interface portion between both vertically adjacent bumps in the figure is the most constricted portion. Also, in point of strength, the bonded interface portion is the lowest. As to the height H between the chip and the substrate after compression bonding, there is obtained a height H of about 70±10 μm. Thereafter, the compression-bonded product is taken out into the atmosphere, a dam 19 is formed on the substrate, then resin 9 superior in fluidity is poured and cured, and lastly solder bumps 10 are formed on the external connection terminals to complete a package.

The following effects are obtained by this embodiment. 1) Since Al electrode pads of the chip and the internal connection terminals of the organic carrier substrate are connected to each other by a flip chip bonding method, the pads can be arranged areawise and the pad pitch can be moderated, even in the case of a multi-pin LST chip, thus permitting the chip to be mounted onto a semiconductor package. 2) Because of the structure wherein the chip and the organic carrier substrate are electrically connected to each other over the shortest distance, a package of a high transmission speed can be constituted, which package can make the most of the performance of a high-speed processing LSI chip. 3) Since the chip-to-substrate bonded distance is 50 μm or more, the strain induced in each Au bump column is diminished. 4) Because of the structure wherein the strain induced by a difference in thermal expansion between the chip and the substrate is absorbed at the central part of the Au bump column, a high-stress is not applied to the weakest Al pad/Au bump bonded interface. 5) Au is higher in strength and longer in fatigue life than solder, and the temperature cycle life of the bonded portion in the package is long. 6) When the package is mounted on a printed wiring board, a large heat strain is not developed on the solder bumps which bond the two with each other because the external connection terminals are formed on the organic carrier substrate having the same thermal expansion coefficient as that of the wiring board. 7) Because of the above effects 3) to 6), the temperature cycle reliability of the internal and external bonded portions in the package becomes extremely high. Moreover, by the adoption of a new bonding/assembling process, it becomes possible to effect a high-strength bonding in a small bonding load condition, so that the likelihood of chip damage in the bonding process decreases and it is possible to realize a mounting process which is capable of affording a high yield. That is, an ultra-multi-pin high-speed LSI chip can be mounted to a highly reliable semiconductor package affording high yield without deteriorating the performance.

Further, according to this embodiment, since the connection is completed in a chip projection area and in a face-down bonding manner, a plurality of chips can be mounted in proximity to one another. Consequently, in a multi-chip package, the package size can be reduced considerably. Besides, since the heat resistance of the intrapackage bonded portion is the same as that of a package based on the conventional Au wire bonding technique, the same solder reflow process as in the prior art can be adopted for mounting the package to a wiring board.

FIG. 3 shows another example of a sectional view of a structure of a semiconductor package according to the present invention. In the same figure, as an organic carrier substrate there is used a tape substrate comprising a polyimide tape 13 having apertures and combined internal-external connection terminals 14, the terminals 14 having been subjected to patterning, and each is formed by a surface and a back of the same Cu land. On each side of each connecting terminal, Ni plating is applied as an undercoat and Au plating is applied to the outermost surface. On the aperture-side, internal connection terminals are formed Au bumps 16, which are bonded to Au bumps 15 formed on Al or Au electrodes 12 of an LSI chip 11. The Au bump bonding is performed in the following manner. First, the substrate-side Au bump surfaces are cleaned by Ar ion sputtering and the substrate is fed into a bonding chamber which is hermetically sealed without exposure to the air and which is held in a dry atmosphere at a partial pressure of steam of not higher than 100 Pa. The chip formed with Au bumps is heated in a vacuum chamber, allowing adsorbed water to be desorbed, and is then fed into the bonding chamber. In the bonding chamber, the Au bumps on the substrate side and the Au bumps on the chip side are aligned with each other and the chip is mounted on the substrate while facing down, followed by the application of heat and pressure from the chip side with use of a bonding tool, and bonding is carried out by scrubbing several times at an amplitude of 5 to 10 μm or by ultrasonic oscillation. At this time, by deformation control, the Au bumps are prevented from being excessively crushed and a chip-to-substrate gap of 50 μm or more is ensured. Resin 17 is filled and cured in the gap between the chip and the substrate and thereafter solder bumps 18 free of lead and having a liquid phase temperature of 190° C. to 230° C. are formed on the external connection terminals of the substrate. This package is designed so that the chip and the substrate are of the same size.

According to this embodiment, for the same reason as that in the embodiment of FIG. 1, an ultra-high speed processing LSI chip can be mounted to a small-sized package without deteriorating its characteristics. Moreover, there is obtained an effect such that, when the package is mounted on a wiring board at the same time, a long-term reliability of inner and outer bonded portions of the package can be rendered extremely high. There also is obtained an effect such that the size of a multi-chip package can be reduced to a great extent.

Further, in this embodiment, the size of the chip and that of the tape substrate are the same and all the bonded portions on a projection surface are accommodated inside the chip surface. Therefore, if a plurality of semiconductor integrated circuit devices (say, LSI) having Au bumps are formed on a single Si wafer and this wafer is mounted on a tape substrate with patterns for plural packages formed thereon, followed by separation by cutting in the final process after the formation of solder bumps, then it becomes possible to assemble a plurality of chip-size packages at a time, and hence, it is possible to greatly reduce the manufacturing cost. The manufacturing method is the same as that used in the embodiment of FIG. 1.

This embodiment is suitable for a case where the number of pins is not larger than 200.

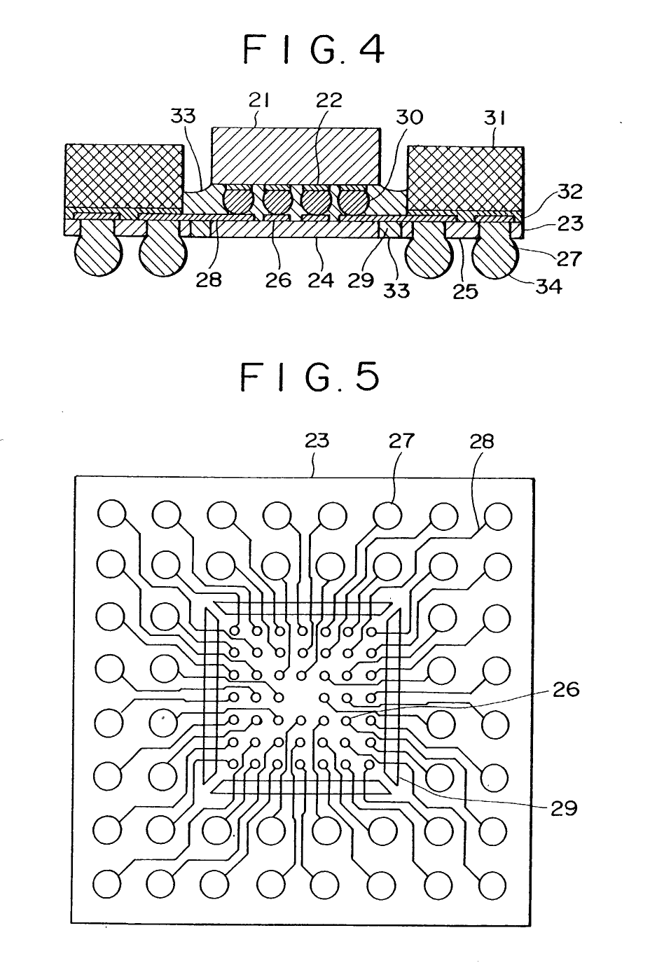

FIG. 4 shows a further example of a sectional view of a structure of a semiconductor package according to the present invention and FIG. 5 is a plan view of an organic carrier substrate used in FIG. 4. The organic carrier substrate is a tape substrate comprising a polyimide tape 23 and an etched Cu foil pattern bonded to the tape. The polyimide tape has an external connection terminal portion and apertures formed along a boundary between an internal connection terminal area 24 and an external connection terminal area 25. The latter apertures are formed as slits 29, which slits are each of a size not permitting transmission of a tape strain in the internal connection area to the external connection area. The Cu foil pattern comprises internal and external connection terminals 26 and 27 and wiring portions 28 passing through the slits 29. The internal connection terminals 26, which are plated with Au on the tape substrate, and Au bumps 30 formed on electrode terminals 22 of a chip 21 are bonded together metallically. According to the bonding method adopted herein, first the surfaces of the internal connection terminals on the tape substrate are cleaned by sputtering with Ar ions, then the chip is mounted on the substrate while positioning it in a dry atmosphere of not higher than 100 Pa as a partial pressure of steam, then the entire temperature is raised to 200° C. by heating, and compression bonding is carried out by the application of pressure and ultrasonic oscillation from the chip side. A reinforcing plate 31 having a thermal expansion coefficient equal to that of the wiring board which is for mounting the package thereon, is affixed with an adhesive 32 to the chip mounted side in the external connection terminal area. A highly fluid resin 33 is poured and cured between the chip and the substrate. When the resin is poured, a backup member is used to prevent leakage of the resin from the slit portions 29, which slit portions are also filled with the resin to be cured. Thus, the wiring passing through the slits are covered and protected with the resin.

According to this embodiment, an ultra-multi-pin LSI chip having 150 pins or more as the number of electrode terminals can be bonded securely to the terminals of the tape substrate by a flip chip bonding method using a high melting material having a long fatigue life and a high resistance to environment. Consequently, an ultra-multi-pin and ultra-high speed processing LSI chip can be assembled to a plastic package of low cost and high reliability in a mounted state on a wiring board. When the package according to this embodiment is mounted on a wiring board, a heat strain induced by a difference in thermal expansion between the chip and the carrier substrate is shut off by the slit portions and the thermal expansion coefficient of the external connection terminal area becomes approximately equal to that of the wiring board. Therefore, a large thermal stress is not developed in the solder bump connections and the temperature cycle life of the solder bump connections becomes very long.

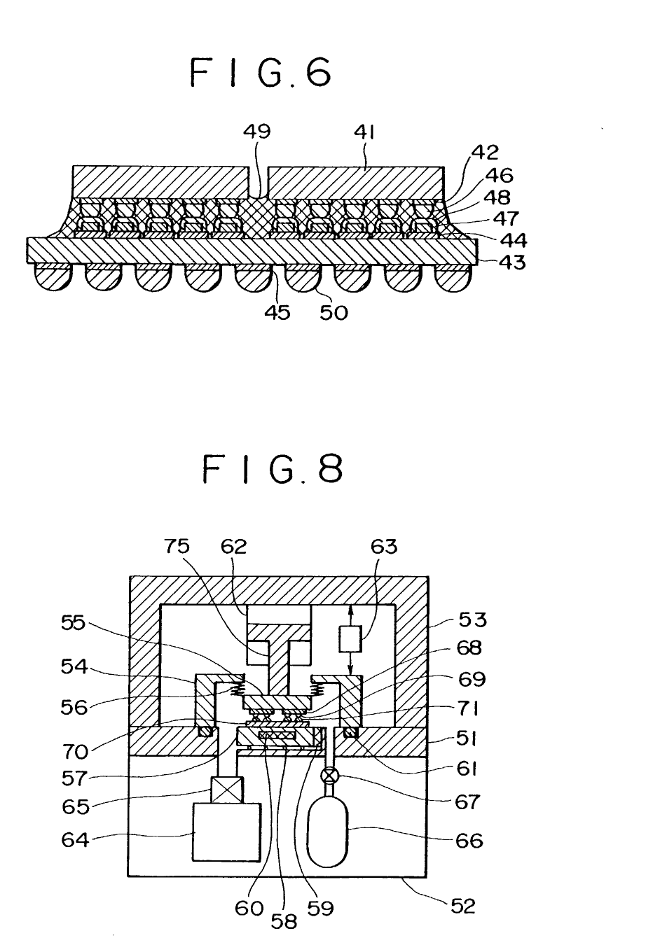

FIG. 6 shows an example of a sectional view of a structure of a multi-chip package according to the present invention wherein a plurality of chips are arranged close to one another at intervals of 1 mm or less. In the same figure, internal connection terminals 44, external connection terminals 45 and wiring patterns are formed on both surfaces of a module substrate 43. A thick Ni plating 47 is applied as an undercoat to the internal connection terminals and Au plating 48 is applied onto the undercoat to form Au bumps. On Al electrode pads 42 of a chip 41 are formed Au stud bumps 46 by a wire bonding method. The Au bumps on the substrate side and those on the chip side are bonded together in the following manner. The surfaces of the Au bumps on the substrate side are cleaned by sputter cleaning, then the Au bumps thus cleaned are fed into a bonding chamber sealed hermetically without exposure to the air and filled with a dry atmospheric gas, while the chip-side Au bumps are heat-treated in a vacuum to remove adsorbed water and organic matter, then both bumps are aligned, opposed to each other, and bonded together by the application of heat, pressure and scrubbing oscillation. A plurality of chips are bonded to the module substrate and resin 49 is filled between the chip and the substrate. On the back of the module substrate are formed solder bumps 50 having a liquid phase temperature of 190° C. or higher for connection with a mother board. As an external connecting mechanism there may be adopted a structure wherein the solder bumps are replaced by lead terminals and the lead terminals are soldered to a mother board.

In this embodiment, since the module substrate-chip connection portion comprises a metallic bonding of highly strong Au bumps with each other, the temperature cycle reliability of the internal connection is high and there are no restrictions on the heating temperature at the time of soldering to a mother board because the bonded portion has heat resistance. Moreover, chips can be mounted on the module substrate in close proximity to one another to such a degree that adjacent chips are in contact with each other, thus permitting the module size to be reduced to a minimum.

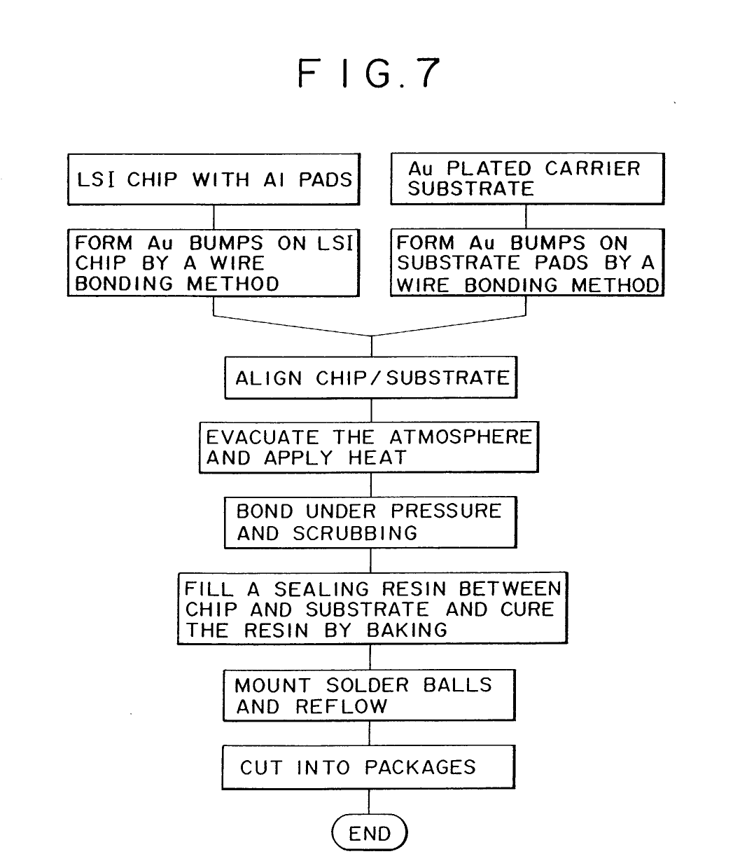

FIG. 7 shows a bonding procedure adopted in the bonding method according to the present invention. Au bumps formed by a ball wire bonding method are high in the purity of Au as bump material and are soft, and therefore, they can be formed in a step just before flip chip bonding. For this reason the degree of cleanness of the bump surfaces is high. Consequently, it is possible to omit the surface cleaning treatment for both bumps. Chips are mounted on the carrier substrate at atmospheric pressure while being aligned, then in this state, the ambient atmosphere is evacuated to 100 Pa or less, followed by heating, allowing moisture and organic matter adsorbed on the bump surfaces to be desorbed, and then compression bonding is performed. At this time, if scrubbing is performed plural times together with pressing at an amplitude of several μm to ten odd μm or if ultrasonic oscillation is applied, it is possible to improve the bonding strength easily. The positioning of the chips is performed in the air while setting the substrate and the chips to the bonding system. After the positioning, a load of several grams or less per bump is applied to each of the chips with use of a pressing jig. In this way, it is possible to prevent the occurrence of a positional deviation between the chips and the substrate during the pressing and to expose the bonding area to a vacuum atmosphere as large as possible, thereby allowing adsorbed matters to be desorbed. After the bonding, the substrate with chips is taken out into the air, a liquid resin is penetrated between the chips and the substrate, and then, after the removal of air bubbles, the resin is cured by heating. Thereafter, flux is applied to the Au-plated external connection terminals on the back of the carrier substrate, solder balls are mounted thereon, and the solder is allowed to reflow by heating to form solder bumps. In the case where a plurality of packages are assembled using a single substrate, there is provided, as a final step, a cutting step for cutting off the packages from each other. The assembling process is now completed.

FIG. 8 shows an example of a bonding system for realizing the bonding method illustrated in FIG. 7. In FIG. 8, an upper chamber 54 and a lower chamber 51, which are for evacuation, are in close contact with each other through an O-ring 61. A combined pressing jig and vacuum flange 55 for pressing chips 68 is integral with a central part of the upper chamber 54 in a hermetically sealed manner through bellows 56. Above the flange is disposed with a cylinder 62 which is fixed to a support arm 53, and a piston 75 of the cylinder 62 is secured to the flange to control vertical movements of the flange. The upper chamber can move up and down independently of the movement of the flange and is controlled by a drive mechanism 63 attached to the support arm. The relative moving distance of the upper chamber and the flange is designed to be 20 mm or more. According to this structure, while a low load is applied to the semiconductor chips 68 by the flange, the upper chamber is pulled up, thereby permitting a position checking camera to be inserted into the chamber. A heat stage 57 for supplying and setting the semiconductor chips 68 and a carrier substrate 700 in a contacted state of Au bumps 69 and Au pads 71 is internally provided with a heater 60 and is further provided with a stage driving mechanism 59 for driving the stage right and left slightly. The heat stage is supported by means of a bearing 58 which functions to bear the movement of the heat stage and also bear the bonding load. The size of a space to be evacuated is designed to be a minimum size which permits the chips and the substrate to be received therein, and an evacuating pump 64 is selected so that the time required for evacuation to 10⁻² torr or lower is not longer than 20 seconds. N₂ gas is used as a leakage gas for releasing the chamber pressure to the atmospheric pressure.

Since this embodiment is of a structure wherein the bonding mechanism is disposed outside the vacuum chamber and only the surroundings of a bonding sample can be evacuated, the time required, from the positioning under atmospheric pressure until obtaining a vacuum atmosphere necessary for the bonding, is shortened to a large extent, and a single bonding process comprising substrate-chip registration→evacuation→compression bonding→leak to the air can be done within one minute, thus making it possible to apply the bonding method according to the present invention to mass production. Besides, since scrubbing of several μm or so can be performed from the substrate side in the compression bonding step, it becomes possible to enhance the bonding strength at a low load and hence possible to further diminish the likelihood of chip damage.

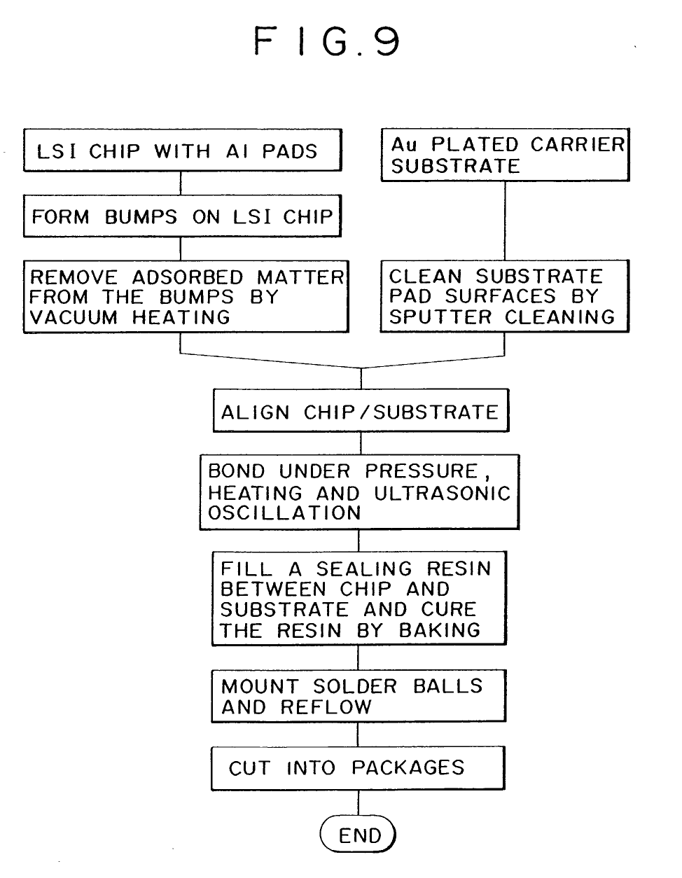

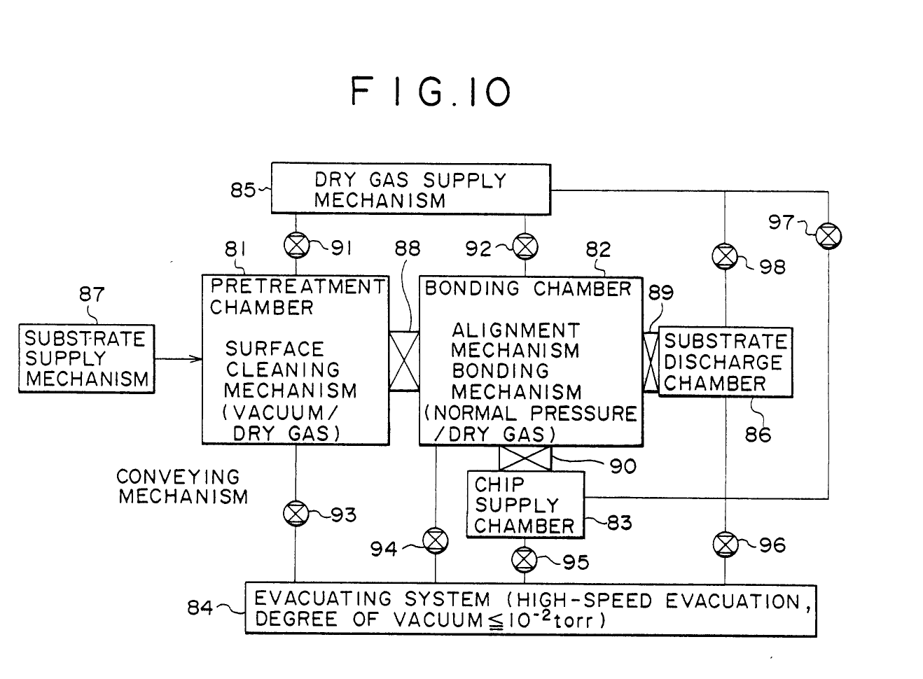

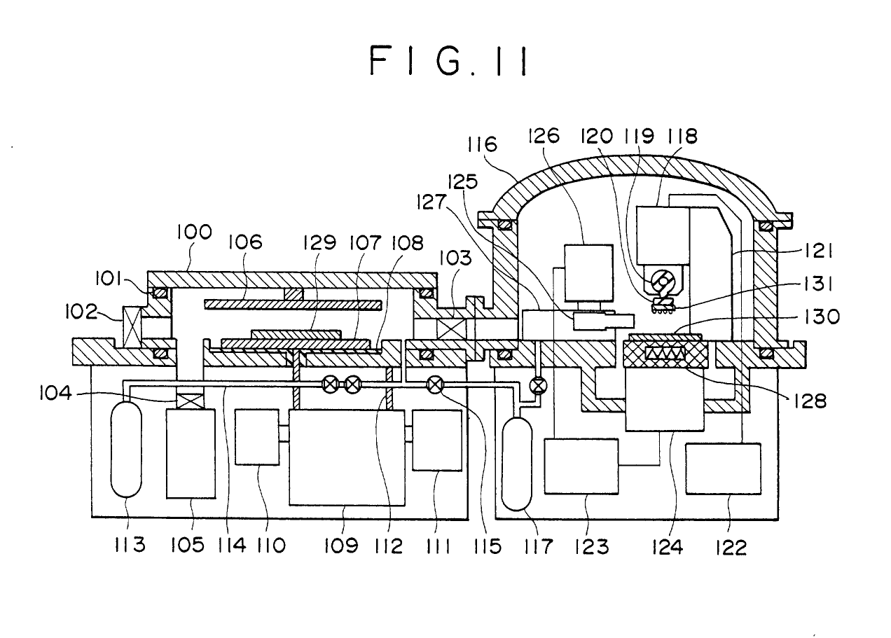

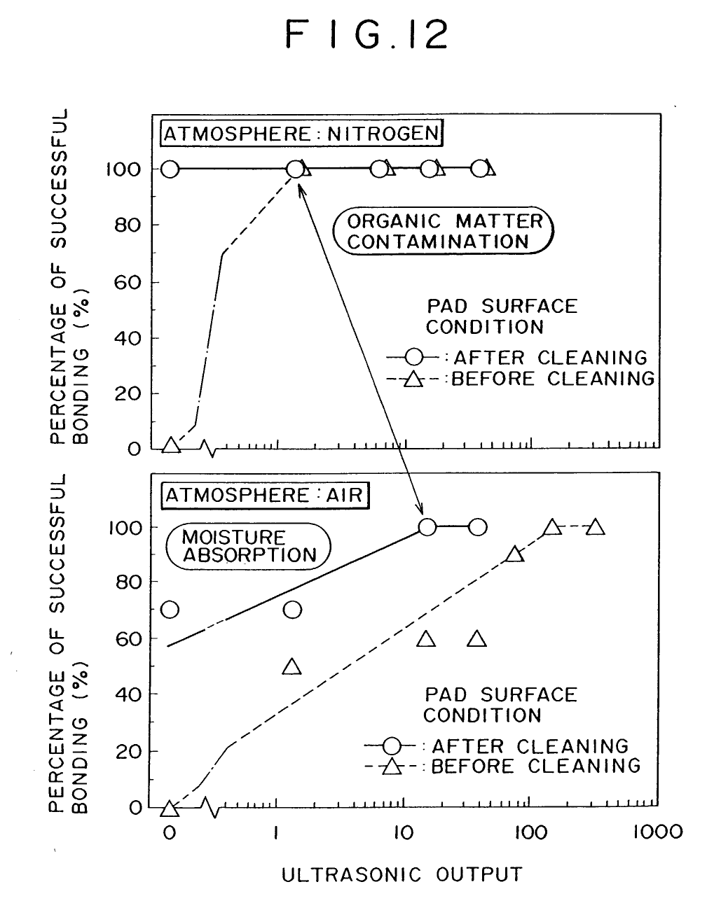

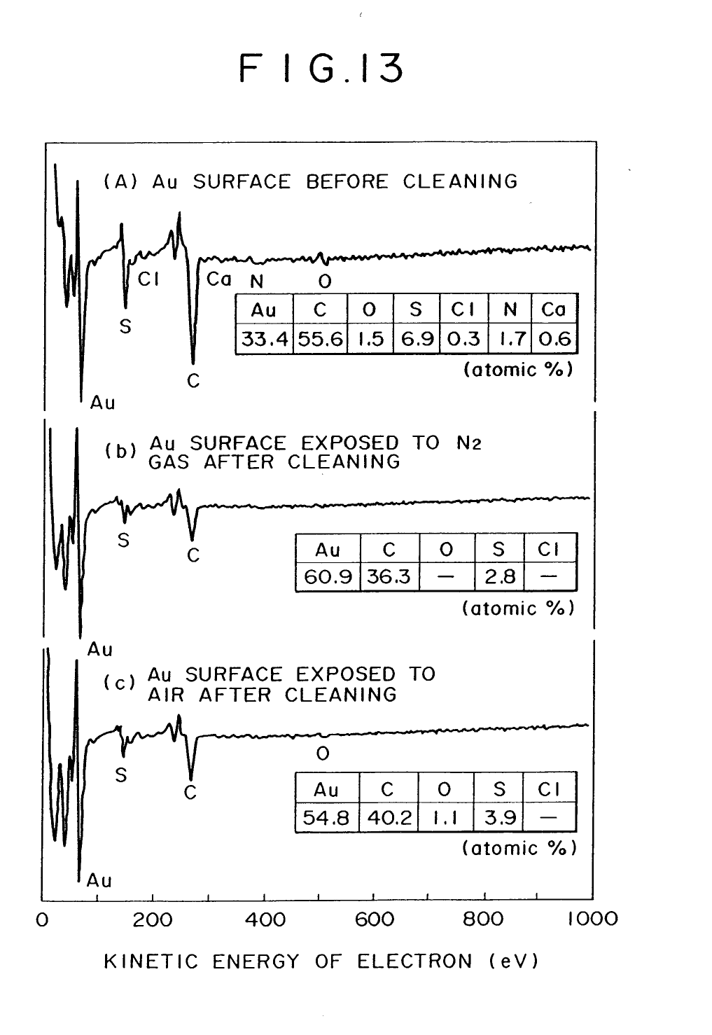

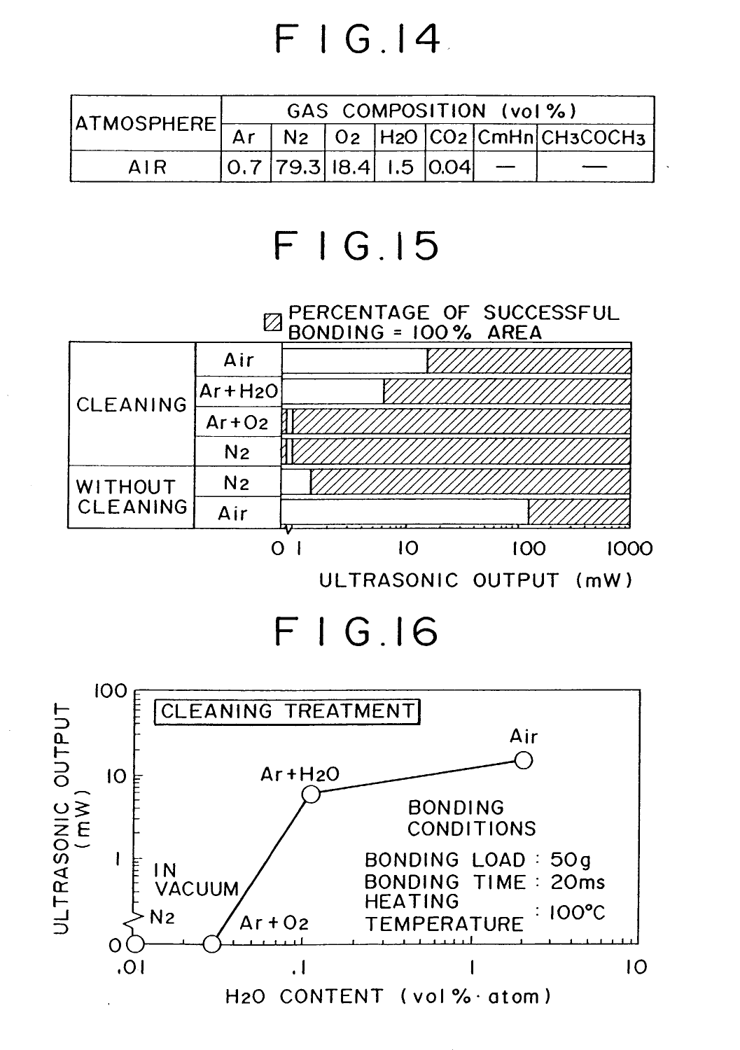

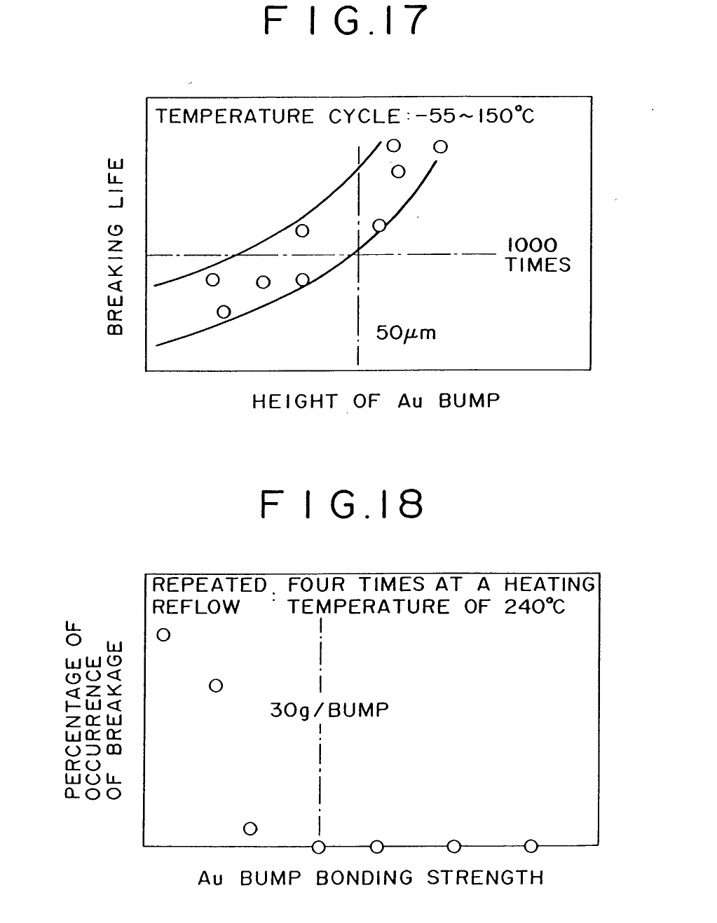

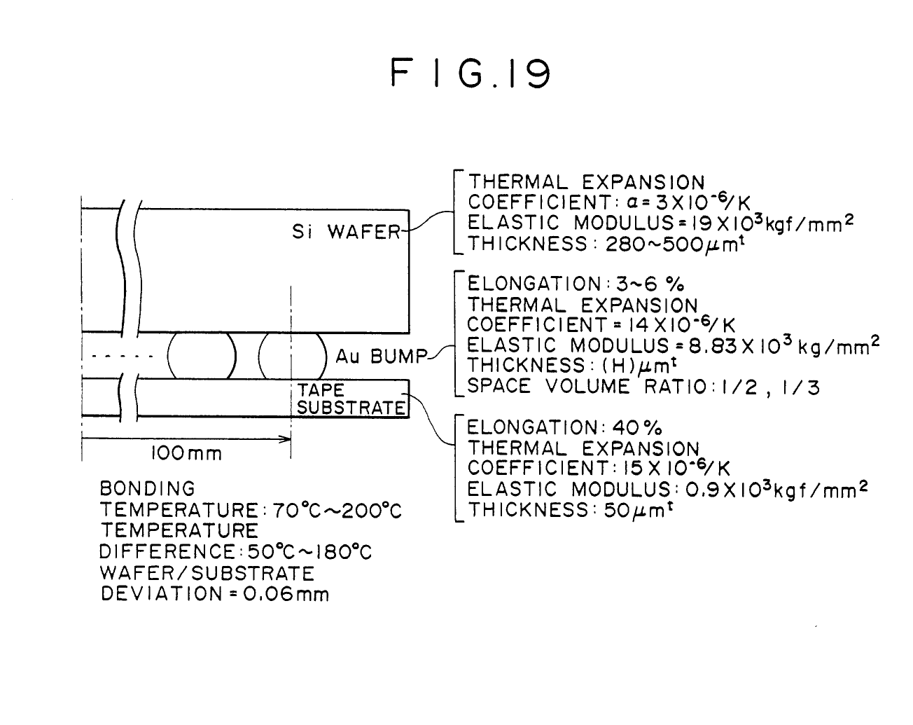

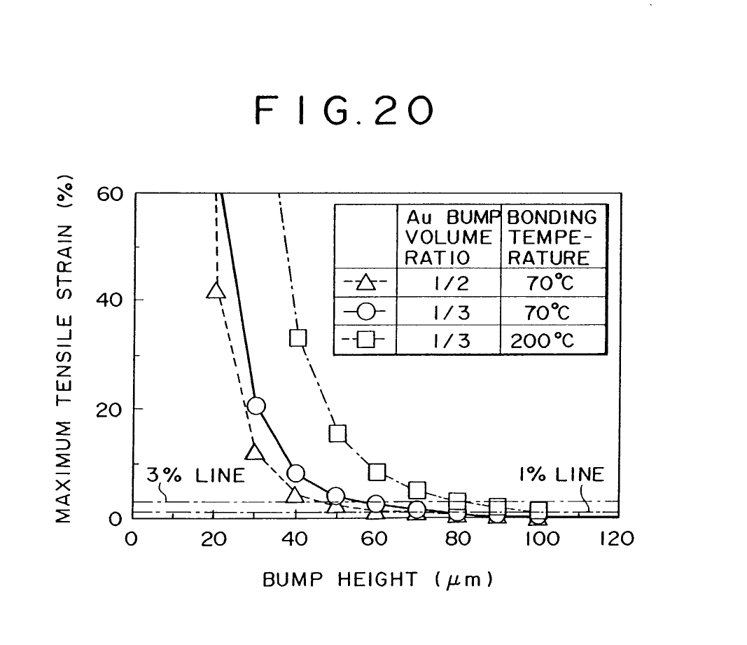

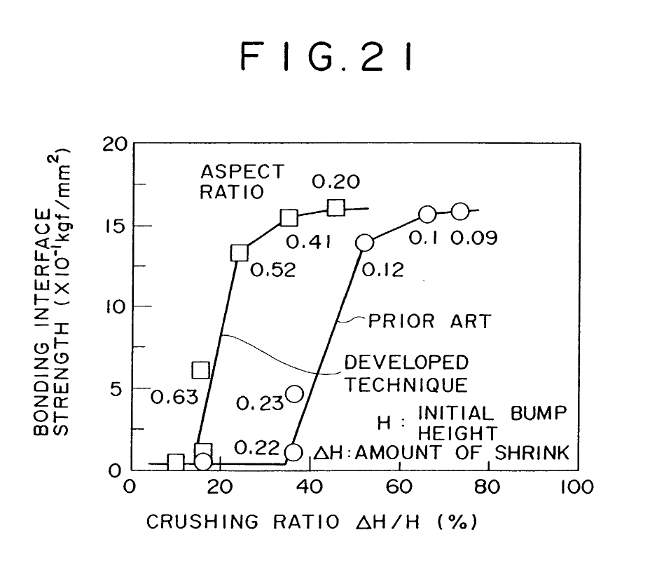

FIG. 9 shows another bonding procedure used in the bonding method according to the present invention. If Au pads or Au bumps formed by plating are formed thicker than several μm, an increase of cost results, so it is necessary to form them to a thickness of not larger than 1 μm. On the other hand, if Au plating is thin, the deformation of Au pads becomes very small and therefore the surface contamination level exerts a great influence on the bonding. In the illustrated procedure, therefore, there are performed a treatment of cleaning the surfaces of the substrate-side Au pads by sputter cleaning and a treatment of heating the chip-side Au bump surfaces in a vacuum only to remove the adsorbed water. After performing both treatments, the components are introduced into a hermetically sealed chamber held at a gas pressure of 5×10³ to 2×10⁵ Pa or more and in a dry air atmosphere of 100 Pa or less as a partial pressure of steam in a contactless state with the atmosphere or in a gaseous atmosphere consisting mainly of N₂ or Ar, the substrate is put on the heat stage, while the chips are chucked on the pressing jig by vacuum suction, and then the substrate and the chips are aligned with each other and subjected to compression bonding under scrubbing or ultrasonic oscillation. In the case where the substrate used is composed of patterns corresponding to plural packages, chips are fed successively for bonding. After the bonding, the module thus obtained is taken out into the atmosphere, then resin is filled between the chips and the substrate and is cured, solder bumps are formed on the substrate-side external connection terminals, followed by cutting into the plural packages. The assembling work is now completed.

FIG. 10 shows an example of a bonding system for realizing the bonding method illustrated in FIG. 9. The bonding system basically comprises a pretreatment chamber 81 for cleaning pad surfaces of a substrate; a chip supply chamber 83 for heat-treating a semiconductor chip in a vacuum and supplying it to a bonding chamber about to be described; a bonding chamber 82 for aligning the substrate and the chip with each other and for bonding the two under the application of heat and pressure and under conditions of scrubbing or ultrasonic oscillation; a substrate discharge chamber 86 for taking out the substrate with the chip from the bonding chamber; a dry gas supply mechanism 85 for supplying a dry gas to the pretreatment chamber, bonding chamber, chip supply chamber and substrate discharge chamber, each of which are hermetically sealed; an evacuating system 84 for evacuating each of those chambers; and a substrate supply mechanism 87 for supplying a substrate to the pretreatment chamber. Those chambers are interconnected through gate valves 88, 89 and 90 and a substrate or a chip is conveyed through the chambers. As the dry gas there may be used any gas irrespective of whether it is an oxidizing gas or a non-oxidizing gas insofar as it is not higher than 100 Pa as a partial pressure of steam. Examples are air, nitrogen and argon.

FIG. 11 shows an example of the pretreatment chamber and of the bonding chamber both illustrated in FIG. 10. In the pretreatment chamber 100 there is provided a mechanism for sputtering a carrier substrate 129 with Ar ions. A cathode electrode 107 is disposed in an electrically insulated manner from the system through an insulating member 108. Above the cathode electrode 107 there is disposed an anode electrode 106, which is at the same potential as the ground potential. After the substrate is set onto the cathode electrode and the interior of the chamber is evacuated, Ar gas is introduced and a high-frequency voltage with a direct current component interposed thereon is applied between the electrodes from a high frequency generator 109, allowing a glow discharge to be generated between the electrodes. At this time, Ar gas is ionized and is accelerated toward the substrate by a DC voltage component, whereby the substrate surface is etched physically and cleaned. After the cleaning, nitrogen gas is introduced up to the same gas pressure as in the next bonding chamber 116. In the bonding chamber there are mounted a substrate conveying mechanism 127, an alignment mechanism comprising a camera 125, a drive system 126 for the camera, an XY moving stage 124, a controller 123, a bonding mechanism comprising a pressing mechanism 118, a support arm 121, an ultrasonic oscillation mechanism 119, a bonding tool 120, a controller 122, and a chip supply mechanism which conveys a chip 131 to a bonding tool, though not shown. The bonding chamber is first evacuated while the system is in operation, and a dry nitrogen gas is introduced therein up to near the atmospheric pressure to maintain the interior of the chamber in a dry atmosphere at atmospheric pressure. A substrate 130 is mounted on a heat stage 128 in which is incorporated a heating mechanism. The chip 131 is chucked to the bonding tool by vacuum suction. The camera is inserted between the chip and the substrate to check the position of Au bumps on the chip and that of Au pads on the substrate while alignment is made by the XY moving stage. Then after movement of the camera, the chip is moved downward by the pressing mechanism, and bonding is performed under the application of pressure and ultrasonic wave.

According to this embodiment, even if the Au pads as substrate-side internal connection terminals are, contaminated with organic matter or with an oxidizing metal due to diffusion from the undercoat, since their surfaces are physically etched with Ar ions and cleaned, their bondability to the chip-side Au bumps is greatly improved and a highly reliable bonded portion of high strength is obtained. Besides, since the bonding chamber is kept in a dry nitrogen gas atmosphere at atmospheric pressure having a reduced moisture content, the bondability is not deteriorated, the chip can be chucked by vacuum suction, and the moving components in the drive system can be used over a long service life without causing seizure. Therefore, it is possible to realize a process and system capable of mass production and able to attain a highly reliable chip-carrier substrate bonding. Thus, even in the case of an ultra-multi-pin and ultra-high speed LSI chip with electrode pads arranged areawise thereon, the chip and the organic carrier substrate can be bonded together directly and with a high strength through Au bumps. In this way it is possible to obtain a highly reliable semiconductor package at low cost without deteriorating the chip performance.

According to the present invention, as set forth above, an ultra-multi-pin or high-speed LSI chip can be packaged compactly and the chip performance can be enhanced to the utmost. Moreover, with use of an organic carrier substrate of low cost, it is possible to provide a semiconductor package which is highly reliable in its connections. Further, it is possible to provide an Au bump/Au pad or Au bump/Au bump flip chip bonding method capable of fabricating a semiconductor package through a highly mass-producible process, as well as a bonding system for realizing the said method.

1. A semiconductor package characterized in that it comprises:
a semiconductor chip having electrode terminals;
an organic substrate having internal connection terminals connected to said electrode terminals; and
a resin filled between said semiconductor chip and said organic substrate,
wherein said electrode terminals and said internal connection terminals are bonded together through Au bumps each having a diameter of not larger than 300 μm height of not smaller than 50 μm and a height/diameter ratio of not lower than 1/5.

2. A semiconductor package according to claim 1, characterized in that it has a bonding strength of not lower than 30 g in terms of a tensile breaking strength per bump.

3. A semiconductor package characterized in that it comprises:
a semiconductor chip having a plurality of electrode terminals;
an organic substrate having a plurality of internal connection terminals and a plurality of external connection terminals, said internal connection terminals being arranged dimensionally in the same manner as with said electrode terminals and connected to the electrode terminals through Au bumps, and said external connection terminals being constituted by solder bumps having a liquid phase temperature of not lower than 190° C.; and
a resin filled between said semiconductor chip and said organic substrate.

4. A semiconductor package characterized in that it comprises:
a semiconductor chip;
an organic substrate having a plurality of external connection terminals and a plurality of internal connection terminals which are flip chip-bonded to said semiconductor chip through Au bumps with a pitch of not larger than 400 μm, the area of said external connection terminals and that of said internal connection terminals being divided from each other through slits, and said external connection terminals and said internal connection terminals being connected to each other through wiring which passes through said slits; and
a resin which is filled between said semiconductor chip and said organic substrate and which covers said wiring.

5. A semiconductor package characterized in that it comprises:
a semiconductor chip;
an organic substrate having a plurality of internal connection terminals arranged areawise and bonded in a face-down manner to said semiconductor chip and a plurality of external connection terminals arranged areawise, the area of said internal connection terminals and that of said external connection terminals overlapping each other on a projection surface; and
a resin filled between said semiconductor chip and said organic substrate.

6. A semiconductor package according to claim 5, characterized in that a pair of said internal connection terminal and said external connection terminal are formed on a back and a surface of a single Cu land.

7. A semiconductor package characterized in that it comprises:
a plurality of semiconductor chips having electrode terminals and arranged at intervals of not larger than 1 mm;
an organic substrate having a plurality of internal connection terminals connected to said electrode terminals through Au bumps and a plurality of external electrode terminals constituted by solder bumps having a liquid phase temperature of not lower than 190° C.; and
a resin filled between said semiconductor chips and said organic substrate.

8. A flip chip bonding method for an organic substrate and a semiconductor chip, characterized in that it comprises the steps of: forming Au bumps on electrode terminals of the semiconductor chip, forming an Au plating layer on surfaces of internal connection terminals of an organic carrier substrate or a tape substrate, subjecting Au bonding surfaces of a substrate-side bonding portion and of a chip-side bonding portion to a cleaning treatment so as to give an Au concentration of not lower than 20 atom %, and compression-bonding said surfaces in a dry atmosphere of not higher than 100 Pa as a partial pressure of steam without exposure to the atmosphere and under the application of heat and pressure.

9. A flip chip bonding method according to claim 8, characterized in that said cleaning treatment for the substrate-side bonding portion is sputter cleaning using Ar ions, the bonding atmosphere is at a partial pressure of steam of not higher than 100 Pa and comprises a gas consisting principally of air, nitrogen, or Ar having a pressure of 5×10³ to 2×10⁵ Pa, and the compression bonding is carried out with scrubbing or ultrasonic oscillation simultaneously with the application of heat and pressure.

10. A flip chip bonding method for an organic substrate and a semiconductor chip characterized in that it comprises the steps of: forming Au bumps on electrode terminals of the semiconductor chip and on internal connection terminals of an organic carrier substrate or a tape substrate by an Au ball bonding method, aligning the Au bumps of a substrate-side bonding portion and the Au bumps of a chip-side bonding portion with each other under atmospheric pressure, forming a hermetically sealed space in that state or conveying the substrate and the chip after registration into a hermetically sealed chamber, evacuating said hermetically sealed chamber until there is obtained a bonding atmosphere of not higher than 100 Pa, and compression-bonding the substrate and the chip under the application of heat and pressure or with scrubbing or ultrasonic oscillation simultaneously with the application of heat and pressure.

11. A flip chip bonding system characterized in that it comprises:
a hermetically sealed pretreatment chamber for cleaning surfaces of Au pads formed on a substrate;
a hermetically sealed bonding chamber for compression-bonding the Au pads on the substrate and Au bumps formed on a semiconductor chip with each other under the application of heat and with scrubbing or ultrasonic oscillation while maintaining a dry atmosphere;
a hermetically sealed chip supply chamber for supplying the semiconductor chip with Au bumps to said bonding chamber; and
a hermetically sealed discharge chamber for taking out the thus-bonded semiconductor chip and substrate into the atmosphere,
wherein said pretreatment chamber and said bonding chamber, said bonding chamber and said chip supply chamber, and said bonding chamber and said discharge chamber are respectively connected through gate valves.

12. A flip chip bonding system characterized in that it comprises:
a bonding mechanism for the application of pressure and heat;
a supply mechanism for supplying a substrate and a semiconductor chip to said bonding mechanism;
a hermetically sealed vessel in which said semiconductor chip and said substrate are set; and
an evacuating mechanism,
said hermetically sealed vessel being divided into an upper vessel and a lower vessel, said upper vessel comprising a component connected to a pressing mechanism and a component contacted closely with said lower vessel through an O-ring, both components being joined together in a hermetically sealed manner through a relatively movable bellows.

13. A semiconductor package fabricating method characterized in that it comprises the steps of:
subjecting a semiconductor wafer formed with a plurality of semiconductor integrated circuit devices having Au bumps and an organic substrate for a plurality of packages formed with Au bumps or Au pads to a surface cleaning treatment;
thereafter compression-bonding a semiconductor wafer and said organic substrate with each other under the application of heat and with scrubbing or ultrasonic oscillation;
pouring and curing a resin between said semiconductor wafer and said organic substrate;
subsequently forming solder bumps on external connection terminals of said organic substrate; and
thereafter assembling a plurality of chip-size packages by a cutting operation.
